(19) United States
(12) Patent Application Publication
(10) Pub. No.: US 2002/0113586 A1
(43) Pub. Date: Aug. 22, 2002

(54) Method and apparatus for offset correction

(76) Inventors: Edward Shan-Wei Ho, San Gabriel, CA (US); Emil Chao, Laguna Hills, CA (US); Parameswaran Gopal Iyer, Irvine, CA (US)

Correspondence Address: Chad W. Miller, Weide & Associates, Ltd., 11th Floor, Suite 1130, Phoenix Bldg., 330 South 3rd Street, Las Vegas, NV, 89101, US

(21) Appl. No.: 09/792,362

(22) Filed: Feb. 22, 2001

(51) Int. Cl. G01R 23/165

(52) U.S. Cl. 324/76.29

(57) ABSTRACT

A method and apparatus for offset detection and correction is disclosed. In an active amplifier or filter system, or any system that may suffer from unwanted offset, the invention monitors for periods when an input, i.e. reference value, may be predicted or is known. When such a period is detected, the offset detection and correction system records the offset and compares it to the known or predicted reference value. Based on the comparison the amount of offset can be determined. In one configuration, the offset is determined to be greater than or less than the reference value. A digital value is thus provided to correction logic to control an output value. This output value increments or decrements a counter. The output of the counter feeds into a digital to analog converter. The output of the digital to analog converter is provided by into the system that suffers from offset to correct or counter the unwanted offset. Control logic, comparators, pattern detection systems, counters and digital to analog converters may be used to implement the invention.

### FIELD OF THE INVENTION

The present invention relates to semiconductor devices and systems incorporating semiconductor devices, and in particular, semiconductor devices that suffer from offset.

### BACKGROUND OF THE INVENTION

As technology advances there is a desire for higher processing speeds and higher data transmission speeds. In some applications the quest for higher speeds may be achieved by manipulating the configuration of one or more semiconductor devices. For example, transistors, such as field effect transistors (FET), may be made to switch more rapidly by minimizing the gate area of the FETs while maintaining high transconductance values. As a result, FETs are often configured to maximize channel widths while minimizing channel lengths (large W/L ratio and small gate area).

Disadvantages of these design parameters arises due to FET mismatch. FET mismatch becomes a much greater problem for FET's with short channel length because the variance in semiconductor processing parameters becomes a larger percentage of the overall gate size as the gate size is reduced. FET mismatch is the major cause of system offset (DC offset).

Offset may also occur due to changes in temperature in the device. This type of offset is a function of device temperature. Thus the amount of offset may vary.

The effect of FET mismatch may best be described by providing example drawbacks that occur when the FETs are part of a Gm-C filter. A Gm-C filter constructed with mismatched FETs will not provide a zero output when provided with zero input. Hence the Gm-C cell will have a DC offset. This is generally undesirable because in many instances a zero, or any other input, may result in an output that is slightly different than the input. Subsequent circuitry, such as an analog to digital converter, that receives the output of the Gm-C cell may thus interpret the output as a different value than intended due to the offset. Another example of an undesirable effect of offset is that offset may reduce the linear range of circuit operation.

One proposed solution is to detect the offset by forcing the input of a circuit to zero and then monitoring the output when the known zero input is provided. The method of zeroing the input comprise forcing or connecting the input to ground. This is the method proposed by U.S. Pat. No. 5,061,900. However, this method presents additional problems that are not acceptable for many applications. One such additional problem is that this prior art method requires that the input to the system with offset be forced to zero during the CALIBRATION phase. This is unacceptable because this does not allow the system to continue operation. In a continuous data system data would be lost during the calibration stage. As is understood, loss of data may be unacceptable. Even if the inputs are not shorted to ground, the CALIBRATE mode described in the prior art reference places the system in non operational status either by ignoring the input or resetting the offset correction. Resetting the offset correction will cause the output to provide false results for a period of time. This is unacceptable. This prior art reference does not teach or suggest a method or apparatus to overcome these drawbacks. In addition, the prior art system does not operate in real time or dynamically during circuit operation. Thus, during circuit operation, the prior art system is not able to dynamically or in real time adjust the offset. It may only be done at specific times.

Therefore, a need exists in the art for an improved method and apparatus for offset correction. In one embodiment the invention provides a solution to these problems by providing a system and method to automatically zero the output of the Gm-C cell to counter-act the offset that occurs from the mismatched FETs.

### SUMMARY OF THE INVENTION

The invention provides a system and method to correct for offset in a system, circuit, or device suffering from offset. Offset is defined as the difference between the intended output and the actual output. In one embodiment the invention creates a compensation signal that is fed back into the circuit to adjust the actual output to make it more closely match the desired output. The invention provides the advantage of adjusting or compensating for the offset dynamically and in real time without disrupting the operation of the circuit or device for which the offset is being corrected. Thus, the invention is not required to enter a calibration mode or reset the compensation value every time an adjustment to the compensation value is required. This provides an advantage over the prior art by achieving offset correction without corrupting or losing data. This is particularly desirable in systems with high data rate or systems in which data loss or corruption, even for a short period, is undesirable.

In one embodiment, an offset correction module for correcting offset in a system comprises an input detector connected to monitor the system output for a output indicating that the input is equal to the reference value. A comparator connects to the system to receive the output and compare the output to the reference value and provide an output indicative of the comparison of the system output to the reference value. The output of the comparator connects to a counter controlled by the comparator. The counter is configured to provide a digital signal to a digital to analog converter wherein the digital signal is representative of an offset correction value. A digital to analog converter is configured to convert the digital signal to an analog signal and couple the analog signal to the system to thereby correct the offset. The digital and analog signal are representative of amount of offset correction to feed back into the system to corrected the unwanted offset.

Various other embodiments or features include an embodiment wherein the output indicative of the comparison comprises a logic value indicating whether the system output is greater than or less than the reference value. In one embodiment, the counter comprises an up/down counter. The input detector may predict the input based on consecutive output values. It is contemplated that the system be connected to or operate with a plurality of offset correction modules.

One example method of operation comprises use with an active filter in a packet processing device wherein the packet processing device connects to a computer network. This method comprises analyzing the output of the active filter for an output near a reference value and then comparing the output to the reference value. Based on the comparison, the operation increments or decrements a counter. Next, the method converts the counter output to an analog signal and then provides the analog signal to the active filter to cause the output to more closely match the reference value.

In various embodiments the reference value comprises a non-zero value. In one method, the comparing the results in a digital output indicative of whether the output is greater than or less than the reference value. In another method of operation, the operation adds the positive or negative analog signal to a node of the active filter.

Further objects, features, and advantages of the present invention over the prior art will become apparent from the detailed description of the drawings which follows, when considered with the attached figures.

### DESCRIPTION OF THE DRAWINGS

FIG. 1 illustrates a block diagram of an example environment of the invention

FIG. 2 illustrates a block diagram of an example embodiment of the invention.

FIG. 3 illustrates a block diagram of an alternative example embodiment of the invention.

FIG. 4 illustrates a flow diagram of an example method of operation.

### DETAILED DESCRIPTION OF THE INVENTION

The invention is a method and apparatus for offset correction. In the following description, numerous specific details are set forth in order to provide a more thorough description of the present invention. It will be apparent, however, to one skilled in the art, that the present invention may be practiced without these specific details. In other instances, well-known features have not been described in detail so as not to obscure the invention. The features and aspects described below may be combined in any combination or alone.

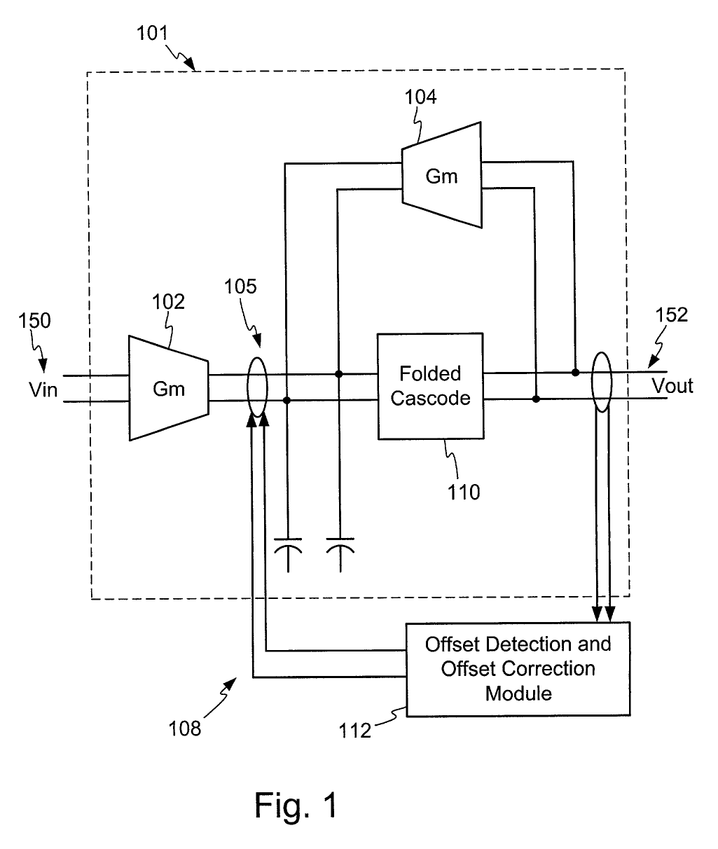

FIG. 1 illustrates an example environment of the invention. As shown, FIG. 1 illustrates a block diagram of an example environment of the invention. As shown a system 101 includes an input 150 and an output 152. The input 150 connects to a Gm cell 102. The output of the Gm cell 102, referred to herein as node 105, connects to another Gm cell 104 and a folded cascode 110. In one embodiment the folded cascode 110 comprises a current buffer configured to control the output impedance at the output node. The node 105 also receives input from an offset detection and correction module 112. The output of the folded cascode 110 is at output node 152. The input of the Gm cell 104 connects to the output 152 and provides its output to node 105. The output 152 in this configuration comprises a voltage, although in other configurations a current output may be generated. The offset detection and offset correction module 112 receives input from the output node 152. The offset detection and offset correction module 112 may provide input to the module at various or a plurality of locations as necessary to compensate or counter for the undesired offset.

The Gm cells 102, 104 and the current buffer together are an active filter. In one embodiment the active filter is configured as a low pass filter. Gain may be incorporated into the device.

The offset detection and offset correction module 112 receives input from the system 101 or monitors the system to determine if the system is introducing an offset into the output. If an offset is detected, then offset correction may occur. In one embodiment offset detection and/or correction occurs in real time. In one embodiment the offset detection and/or correction occurs during system 101 operation and does not interfere with system operation or output. Thus, the invention is particularly well suited for real time, error free operation of system sensitive to data loss or data corruption. One example of such a system comprises a packet processing device in a computer network. For example, one embodiment of a transceiver may process at about 125 megabits per second. Thus, any disruption of a system operation may result in a large amount of data being lost or corrupted. This may be unacceptable because such loss may result in a failure on the part of the device to meet specification or meet customer requirements. In addition, lost packets often generate re-send requests that further burden network capacity.

Due to variations in the device that are used to build the Gm units 102, 104 and the folded cascode 110, the output of the system 101 may not be zero when presented with a zero input. The invention comprises an auto-zero or correction system 112, referred to as an “offset detection and offset correction module” or “module”. This module 112 includes input lines that tap into the output 152 of the system 101 to obtain information about the output and also the input. The module 112 analyzes this data and creates a correction output 108. The output 108 couples to the node 105 output to correct or compensate for the undesired offset. The module 112 operates in real time to continually compensate for the unwanted offset.

Although the exemplary circuit is shown as being sampled at only one point and a correction signal provided to only one point, it is fully contemplated that additional sample and correction points may be added. For example, larger systems may have numerous nodes that are subject to unwanted offset. Numerous correction system 112 may be implemented at various points in the system 101 to determine where unwanted offset is occurring and correct the offset at more than one node as needed.

Offset may be introduced into a system by a number of various factors. One example phenomenon that may introduce offset is transistor mismatch. On example type of transistor that may suffer from mismatch is a field effect transistor. The benefits gained by the invention and the configuration and operation of the invention is not limited to offset occurring for a particular reason. The invention provides a solution to offset regardless of the cause of the offset.

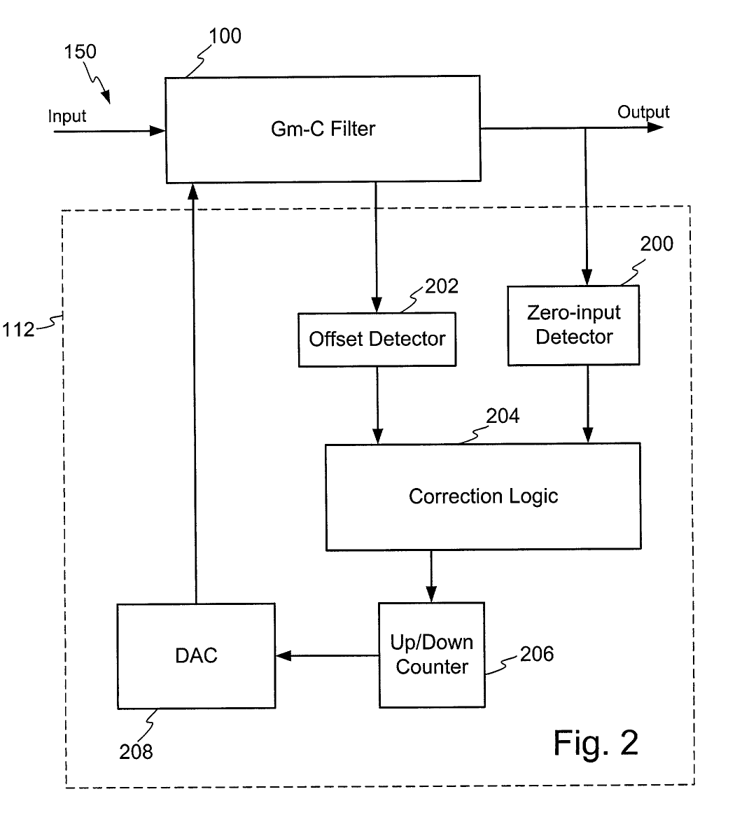

FIG. 2 illustrates an example embodiment of the invention. The module 112 is shown in more detail. The module 112 includes an input detector 200 connected to the output of the filter (i.e., system or circuit) 100. An offset detector 202 also receives input from the system. Although shown as connecting to two different connection points to the system 100, it is contemplated that in other embodiment the offset detector 202 and the input detector may connect to the same point in the system. The input detector 200 may comprise various logic or a pattern recognition device. In one embodiment the input detector 200 comprises a configuration of logic and one or more registers configured to perform an OR function on the output of the system 100. The input detector 200 may hold several previous output values and then compare them on an ongoing basis to thereby search for a desired pattern. Various patterns or other values may trigger the input detector 200 to signal the correction logic 204 of a particular pattern. In one embodiment the input detector 200 signals the correction logic 204 upon output of three consecutive zero values from the system 100. The rate or period can be considered to be dependent on the amount of time it takes for the system output to settle so that the monitored or detected output is considered to accurately represent the input. Detecting for other patterns or values is contemplated.

The offset detector 202 comprises a comparator configured to compare the output of the system 100, to a reference value. In one embodiment the reference value comprises a zero value. Different reference values may be selected. Hence, in the embodiment using zero as a reference voltage, i.e. the input detector 200 monitors for a zero output, then the offset detector compares the output to the zero reference voltage to detect if offset is present. The offset detector may be configured to provide an output comprising a digital signal based on whether any offset is greater than or less than the offset. Thus, the digital signal provides an indication that the offset is greater than the reference or less than the reference.

In another embodiment the offset detector 202 may include an analog to digital converter to convert the amount of offset or the difference between the offset and the reference voltage to a digital value. This digital value may include sign information, such as to indicate whether the offset is greater than or less than the reference voltage. This digital value may then be used to set the counter value or feed directly into the DAC 208 to generate a correction value.

It is also contemplated that the offset detector may continually provide the offset to the correction logic 204 and the correction logic only register, accept, or act on the offset information when so instructed by the input detector 200.

In an alternative embodiment the zero-input detector is configured to monitor for an input other than zero. For example, the zero-input detector could be configured to monitor or detect a particular input value and the offset detector 202 may be configured to determine the offset for that particular input value. Hence, reference points other than zero may be used.

The offset detector 202 and the zero-input detector 200 have outputs connected to correction logic. The correction logic comprises logic or other circuitry configured to cause the counter to count up, count down, or to remain at the same value based on signal from the offset detector 202 and/or the input detector 200. The correction logic 204 may be implemented in various different configurations as might be determined by one of ordinary skill in the art. The invention is not limited to a particular configuration of correction logic.

In one embodiment the offset detector 202, correction logic 204, and counter 206 are configured to determine the offset by comparing the detected offset to a reference value. If the offset is greater than the reference, then the correction logic cause the counter to count down. If the offset is less than the reference, then the correction logic causes the counter to count up. In this manner the counter is either counting up or counting down. Other embodiments may incorporate a no-counter-change state if the offset correction does not require changing or if there is not any offset present. For example hysteresis may be built into the system.

It should be noted that the counter does not need to be reset to adjust the adjustment value, i.e. the counter output. Thus, the offset correction may change in real-time and dynamically to match circuit operation without forcing the system to ground the input to zero to force a zero input. Likewise, the invention provides for continual and accurate data output during the offset correction process and adjustment.

The output of the correction logic 204 connects to an input of a counter 206. Any manner or configuration of counter may be adopted for use. In the embodiment shown in FIG. 2, the counter comprises an up/down counter 206. In one embodiment the counter comprises a 6 bit up/down counter with 5 bit resolution and one sign bit. The up/down counter provides the advantage of dynamically counting or adjusting, i.e. increasing or decreasing, the counter output in real time. Thus, the up/down counter 206 need not be reset during operation to adjust the offset. Hence, the output of the counter does not assume a zero value during the offset correction operation or during an adjustment of the offset correction. The up/down counter may be controlled, at least in part by the up/down counter. In other embodiments the up/down counter is replaced by a more complex correction logic.

The output of the counter 206 connects to a digital to analog converter (DAC) 208. The DAC 208 converts the digital output of the counter 206 to an analog signal that may be provided to the system 100 to provide offset correction. In one embodiment the DAC 208 comprises a 6 bit DAC. It is desired that the voltage level of the offset correction from the DAC 208 accurately cancel any unwanted offset in the system 100. The counter 206 and the DAC 208 are matched bit wise to provide the desired level of resolution in the offset correction. The output of the DAC 208 feeds back into the system 100 to correct for offset or any other unwanted variation in circuit operation.

It is further contemplated that the output of the DAC 208 may be limited in its rate of change. This prevents the correction system from introducing rapid voltage fluctuations into the system. In one embodiment a low pass filter is connected into the circuit after the DAC 208 to prevent high frequency components of the correction signal from passing through the system.

Operation

In operation, the zero-input detector 200 samples the offset. It is contemplated that the sampling occur in real time and on an ongoing and continual basis. This provides accurate offset adjustment during operation of the system 100. In one embodiment the zero-input detector detects a zero input based on three consecutively zero outputs. The zero input is assumed or known based on the output.

When the zero-input detector 200 detects a zero input, it signals the correction logic to accept or process the output from the offset detector 202. In turn, the correction logic 204 evaluates the signal from the offset detector 202. In one embodiment the output of the correction logic is either a logic one or a logic zero.

As a result, the correction logic provides a signal to the counter 206. The signal to the counter 206 causes the counter to increment or decrement the counter output depending on whether the offset is determined to be greater than the reference value or less than the reference value. Consequently the counter 206 generates a digital value that corresponds to or is in some way related to the amount of offset present in the system 100.

The output of the counter 206 couples to a digital to analog converter 208 (DAC). The DAC 208 generates an analog signal that is feed back into the system 100 to compensate for the undesired offset. It is preferred that the offset correction module 112 causes a zero input into the system 100 to result in a zero output from the system. Hence, the offset is removed.

As can be understood, the offset may undesirably increase system output values or undesirably decrease system output values. Consequently, the invention is configured to dynamically add a positive offset signal to the system or add a negative offset signal to the system. Thus, in one embodiment the counter value is centered at zero and the output of the counter may represent a positive number or a negative number.

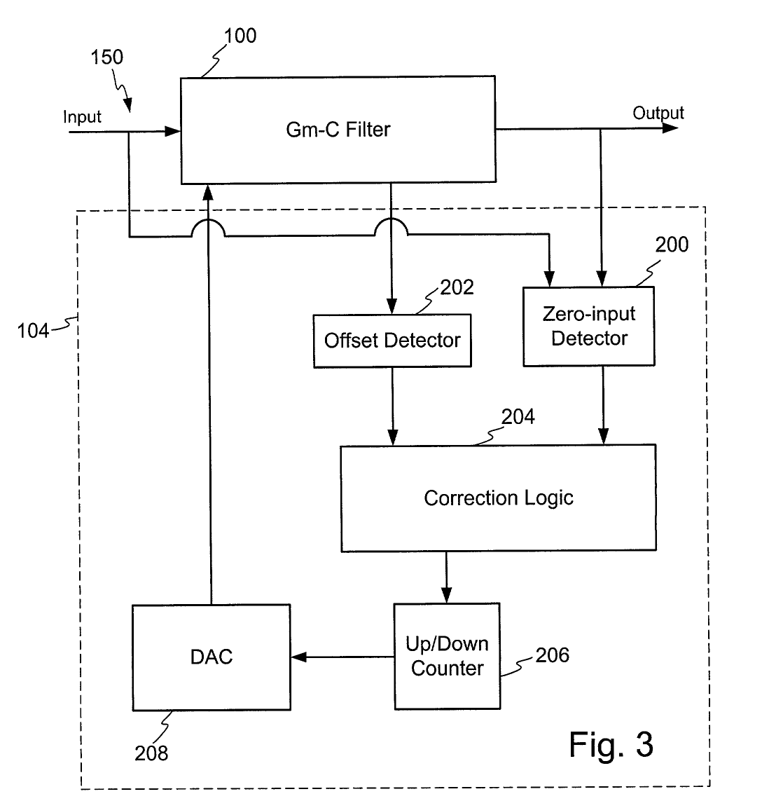

FIG. 3 illustrates an alternative embodiment of the invention. Identical elements are labeled with identical reference numerals. In contrast to the embodiment of FIG. 2, this alternative embodiment includes a connection between the input 150 and the zero-input detector. Connecting the zero-input detector 200 to the input provides an alternative method of determining when a zero input is provided to the system 100. Thus, the input value may be compared to the output value to calculate when offset is occurring.

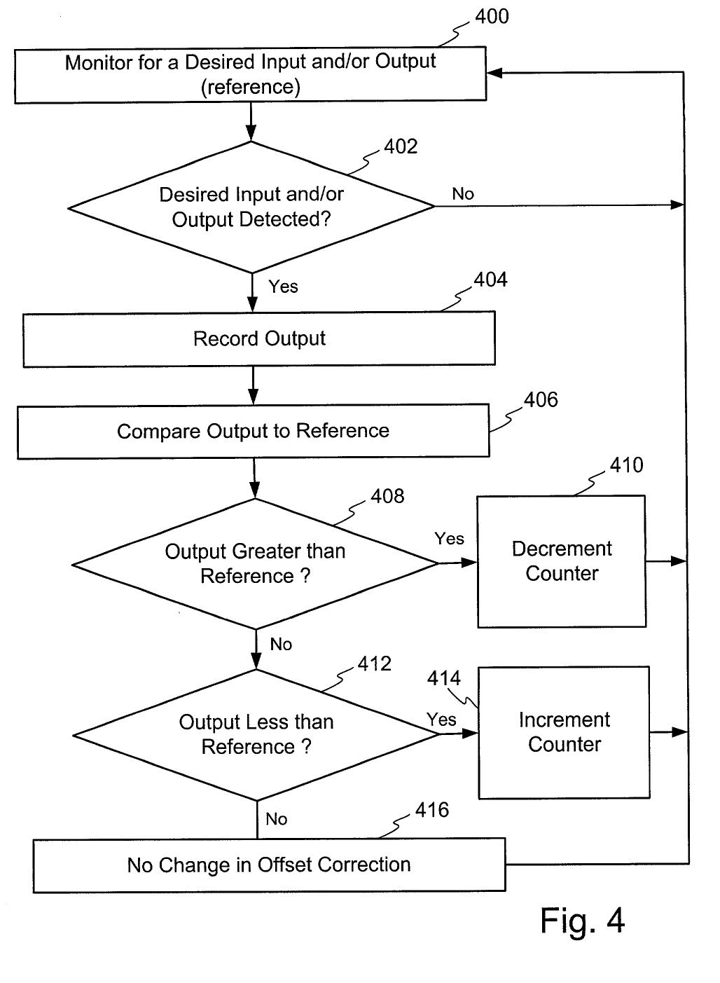

FIG. 4 illustrates an example method of operation. At a step 400, the operation monitors for a desired or a particular input to or output from the system. The monitored input or output can be compared to a reference and any level of unwanted offset detected. At a decision step 402 the operation determines if a desired or particular input and/or output is detected so that offset correction may occur. In one embodiment, the desired input comprises an input near the reference value. If at decision step 402 the desired offset is not detected then the operation returns to step 400. If the desired input or output values are detected, the operation progresses to a step 404. In one embodiment the desired input and or output value is zero. By determining if the output is different the input, the amount of offset can be calculated. The reference value is the value that is being detected at the output that indicates the input if not offset is present or if the offset is corrected. For example, if the output is near zero, it can be predicted that the input was zero.

At a step 404 the operation records or in some way acknowledges the amount of offset. In one embodiment this may occur using the correction logic or a register. Then at a step 406, the operation processes the offset to compare the offset to the reference value. In one embodiment the reference value is zero.

Thereafter, the operation progresses to a decision step 408 where the determination is made whether the offset is greater than a reference. If at decision step 408 the comparison determines the output signal is greater then the reference then the operation decrement the counter the desired amount, at step 410, and thereafter returns to step 400. This causes the output of the counter to become a smaller digital value which in turn reduces the level of compensation introduced by the compensation module 112. If at decision step 408 the offset is not greater then the reference, the operation progresses to decision step 412.

At decision step 412 a comparison occurs to determine if the output is less then the reference. If the output is less then the reference, then the operation progresses to step 414 and the compensation module increments the counter value to increase the amount of compensation from the module. This in turn increases the amount of offset introduced by the module.

If the output is not less then the reference then the operation advances to a step 416. At step 416 no change is necessary and the operation returns to a step 400. Alternatively, step 416 may be omitted and the operation return to step 400 after step 412.

This is but one exemplary method of operation. It is contemplated that other methods of operation or variations to this method may be implemented without departing from the invention and the scope of the claims.

It will be understood that the above described arrangements of apparatus and the method therefrom are merely illustrative of applications of the principles of this invention and many other embodiments and modifications may be made without departing from the spirit and scope of the invention as defined in the claims.

We claim:

1. A method for correcting offset in the active filter, the active filter operating in conjunction with a packet processing device, the packet processing device connected to a computer network, the method comprising:
analyzing the output of the active filter for an output near a reference value;
comparing the output to the reference value;
incrementing or decrementing a counter based on the comparing;
converting the counter output to an analog signal;
providing the analog signal to the active filter to cause the output to more closely match the reference value.

2. The method of claim 1, wherein the reference value comprises a non-zero value.

3. The method of claim 1, wherein the counter comprises an up/down counter.

4. The method of claim 1, wherein the comparing results in a digital output indicative of whether the output is greater than or less the reference value.

5. The method of claim 1, wherein providing comprises adding the positive or negative analog signal to a node of the active filter.

6. The method of claim 1, wherein the active filter includes gain.

7. A method for generating a compensation value to correct undesired offset in a circuit comprising:
monitoring an output of a circuit for an output value generally similar to a reference value;
comparing the output value to the reference value;
generating an offset correction value based on the comparing;
providing the offset correction value to the circuit to thereby compensate for undesired offset.

8. The method of claim 7, wherein the monitoring, comparing, generating and providing occur without disruption to the signals processes by the circuit.

9. The method of claim 7, wherein the circuit is part of a packet processing device.

10. The method of claim 7, wherein comparing includes generating a bit representing whether the output value is greater than or less than the reference value.

11. The method of claim 7, wherein the reference value equals zero.

12. The method of claim 7, wherein monitoring the output provides an indication of the input.

13. An offset correction module for correcting for offset in a system, the module comprising:
an input detector connected to monitor the system output for a reference value;
a comparator configured to compare system output to the reference value and provide an output indicative of the comparison of the system output to the reference value
a counter controlled by the comparator, the counter configured to provide a digital signal to a digital to analog converter, the digital signal representative of an offset correction value;
a digital to analog converter configured to convert the digital signal to an analog signal and couple the analog signal to the system to thereby correct the offset.

14. The module of claim 13, wherein the output indicative of the comparison comprises a logic value indicating whether the system output is greater than or less than the reference value.

15. The module of claim 13, wherein the counter comprises an up/down counter.

16. The module of claim 13, wherein the input detector predicts the input based on consecutive output values.

17. The module of claim 13, wherein the system includes a plurality of offset correction modules.

18. An apparatus to dynamically correct offset in a circuit in a packet processing device comprising;
an apparatus input line configured to receive circuit output;
a detector configured to detect when to dynamically adjust the amount of offset correction;
a comparator configured to compare the circuit output to a reference value and generate a comparator output;
a compensation system connected to the comparator, the compensation system configured to dynamically and in real time generate a compensation value based on the comparator output;
an feedback link configured to provide the compensation value to the circuit in the packet processing device.

19. The apparatus of claim 18, wherein the comparator comprises a differential amplifier.

20. The apparatus of claim 18, wherein the compensation system comprises a digital to analog converter configured to convert the comparator output to a digital value.

21. The apparatus of claim 18, wherein the dynamically and in real time comprises generation of a compensation value without lost of data by the packet processing device.

22. The apparatus of claim 18, wherein the reference value comprises the output without any unwanted offset.
